(19) United States
(12) Patent Application Publication
(10) Pub. No.: US 2025/0220948 A1
(43) Pub. Date: Jul. 3, 2025

(54) POWER SEMICONDUCTOR DEVICE AND METHOD OF MANUFACTURING THE SAME

(71) Applicant: INDUSTRIAL TECHNOLOGY RESEARCH INSTITUTE, Hsinchu (TW)

(72) Inventors: Chih-Hung YEN, Taipei City (TW); Hua-Mao CHEN, Tainan City (TW)

(73) Assignee: INDUSTRIAL TECHNOLOGY RESEARCH INSTITUTE, Hsinchu (TW)

(21) Appl. No.: 18/610,389

(22) Filed: Mar. 20, 2024

(30) Foreign Application Priority Data
Jan. 2, 2024 (TW) 113100050

(51) Int. Cl. H01L 29/778; H01L 29/20; H01L 29/24; H01L 29/34; H01L 29/66

(52) U.S. Cl. CPC H10D 30/475; H10D 30/015; H10D 62/57; H10D 62/80; H10D 62/8503; H10D 99/00

(57) ABSTRACT

A power semiconductor device includes a substrate, an epitaxial layer, a barrier layer, a channel layer, a source pin and a drain pin, and a gate structure. The epitaxial layer is over the substrate and has a top surface that is a rough interface or a capture interface doped with ions. The rough interface is used to disrupt the atomic structure of the top surface, thereby breaking down the two-dimensional electron gas. The ions doped in the capture interface are used to trap the two-dimensional electron gas. The barrier layer is in contact with the top surface of the epitaxial layer. The channel layer is disposed on the barrier layer. The source pin and the drain pin are respectively disposed on two sides of the channel layer. The gate pin is disposed over the channel layer.

### CROSS REFERENCE TO RELATED APPLICATIONS

This application claims priority of Taiwan Patent Application No. 113100050, filed on Jan. 2, 2024, the entirety of which is incorporated by reference herein.

### TECHNICAL FIELD

The present invention relates to a power semiconductor device and its manufacturing method, and in particular the present invention relates to a power semiconductor device that includes an epitaxial layer with a rough interface or a capture interface and its manufacturing method.

### BACKGROUND

Gallium nitride (GaN) power semiconductor devices are made using gallium nitride as the base material. GaN power semiconductor devices have a wider band gap and higher carrier mobility than the electrical properties inherent in silicon (Si) power semiconductor devices. Therefore, GaN power semiconductor devices can be used under high-frequency, high-power operating conditions.

In practice, when GaN is used in transistor outline (TO) packaging or wire bonding packaging, parasitic inductance is likely to occur at the contact points or on the aluminum wires. GaN operating under high-frequency current switching is affected by parasitic inductance, leading to voltage variations (ΔV=L·Δi/Δt). In these cases, GaN power semiconductor devices, accompanied by their induced parasitic inductance, face technical issues such as over-voltage and excessive electromagnetic interference (EMI).

Additionally, GaN power semiconductor devices are currently driven by silicon-based driver circuits (Si-based drivers). The connection parasitic inductance between the silicon driver circuit and the GaN power semiconductor device also suffers from over-voltage and excessive electromagnetic interference (EMI), and the allowable voltage range of a silicon driver circuit is lower than that of a GaN power semiconductor device, making it prone to damage. To avoid damaging the silicon driver circuit due to voltage variations, it is necessary to reduce the switching speed to decrease the voltage change. Therefore, the current technical challenge is to retain the electrical properties of GaN power semiconductors while reducing the parasitic inductance induced by fast switching speeds. One current approach is to propose a method of integrating GaN power semiconductor devices into integrated circuits (IC) and the integration of GaN integrated circuits (IC integration).

However, in manufacturing GaN integrated circuits, another technical issue was discovered. This approach is limited by the process or device characteristics of P-typed gallium nitride metal-oxide-semiconductor (PMOS) (referred to as GaN PMOS). For instance, traditional GaN PMOS utilizes AlGaN/GaN polarization to form two-dimensional electron gas (2DEG) and two-dimensional hole gas (2DHG), achieving a hole channel through 2DHG. However, this process is easily influenced by 2DEG, leading to electron flow and thereby suppressing the current characteristics of PMOS.

### SUMMARY

Some embodiments of the present invention include a power semiconductor device. The power semiconductor device includes a substrate, an epitaxial layer, a barrier layer, a channel layer, a source pin and a drain pin, and a gate structure. The epitaxial layer is over the substrate and has a top surface that is a rough interface or a capture interface doped with ions. The rough interface is used to disrupt the atomic structure of the top surface, thereby breaking down the two-dimensional electron gas. The ions doped in the capture interface are used to trap the two-dimensional electron gas. The barrier layer is in contact with the top surface of the epitaxial layer. The channel layer is disposed on the barrier layer. The source pin and the drain pin are respectively disposed on two sides of the channel layer. The gate pin is disposed over the channel layer.

Some embodiments of the invention include a method of manufacturing a power semiconductor device, suitable for suppressing or capturing two-dimensional electron gas (2DEG). The power semiconductor device includes a substrate and an epitaxial layer over the substrate, and the epitaxial layer has a top surface. The manufacturing method includes the following steps. The top surface is deformed into a rough interface or the top surface is doped to form a capture interface by a surface treatment process. A barrier layer is formed on the epitaxial layer. A channel layer is formed on the barrier layer. A source pin and a drain pin are formed on two sides of the channel layer respectively. A gate pin is formed over the channel layer.

By forming a rough interface or a capture interface on the top surface of the epitaxial layer, the power semiconductor device of the present invention can suppress or capture the two-dimensional electron gas (2DEG) generated due to polarization at the top surface of the epitaxial layer. For example, when the power semiconductor device of the present invention is used as a PMOS power device, it can suppress or capture the two-dimensional electron gas (2DEG) generated due to polarization at the top surface of the epitaxial layer, thereby enhancing the drain current of the PMOS power device. Alternatively, the rough interface or the capture interface can also suppress the two-dimensional hole gas (2DHG) generated due to polarization at the top surface of the epitaxial layer, thereby forming an enhancement-mode PMOS device.

### BRIEF DESCRIPTION OF THE DRAWINGS

FIG. 1A is a partial cross-sectional view illustrating a power semiconductor device according to some embodiments of the present invention.

FIG. 1B is an enlarged view of region E in FIG. 1A according to an embodiment of the present invention.

FIG. 1C is an enlarged view of region E in FIG. 1A according to another embodiment of the present invention.

FIG. 2A to FIG. 2F are partial cross-sectional views illustrating various stages in manufacturing the power semiconductor device according to some embodiments of the present invention.

FIG. 3A to FIG. 3D are partial cross-sectional views illustrating various stages in manufacturing another power semiconductor device according to some other embodiments of the present invention.

FIG. 4A to FIG. 4D are partial cross-sectional views illustrating various stages in manufacturing another power semiconductor device according to some other embodiments of the present invention.

FIG. 5A illustrates the drain current (μA)—gate voltage (V) electrical characteristic curves of the power semiconductor device for different thicknesses of the channel layer.

FIG. 5B illustrates the drain current (μA)—gate voltage (V) electrical characteristic curves of the power semiconductor device when the interface is doped with silicon at different concentrations.

FIG. 5C illustrates the drain current (μA)—gate voltage (V) electrical characteristic curves of the power semiconductor device when the interface is doped with magnesium at different concentrations.

### DETAILED DESCRIPTION

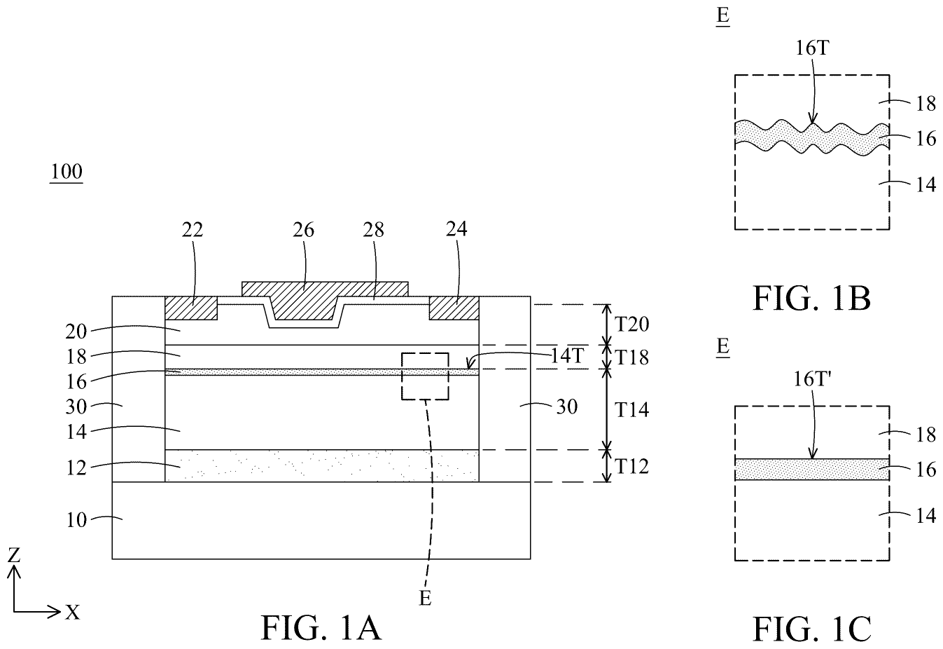

In the following embodiments, the present invention can repeatedly use the same reference numerals and/or labels. These repetitions are for the purposes of simplification and clarity and are not intended to define a specific relationship between the various embodiments and/or structures that are discussed. FIG. 1A is a partial cross-sectional view illustrating a power semiconductor device 100 according to some embodiments of the present invention. FIG. 1B is an enlarged view of region E in FIG. 1A according to an embodiment of the present invention. FIG. 1C is an enlarged view of region E in FIG. 1A according to another embodiment of the present invention. Some components of the power semiconductor device 100 have been omitted in FIG. 1A to FIG. 1C for the sake of brevity.

Referring to FIG. 1A, in some embodiments, the power semiconductor device 100 includes a substrate 10, an epitaxial layer 14, a barrier layer 18, a channel layer 20, a source pin 22 and a drain pin 24, and a gate pin 26. The epitaxial layer 14 is over the substrate 10 and has a top surface 14T. The barrier layer 18 is in contact with the top surface 14T of the epitaxial layer 14. An interface 16 is between the epitaxial layer 14 and the barrier layer 18 (i.e., the top surface 14T of the epitaxial layer 14 as shown in FIG. 1A). The top surface 14T is a rough interface (16T, see FIG. 1B, used to disrupt the atomic structure of top surface 14T) or a capture interface doped with ions (16T′, see FIG. 1C, used to capture two-dimensional electron gas (2DEG)). The channel layer 20 is over the barrier layer 18. The source pin 22 and drain pin 24 are respectively on two sides of the channel layer 20. The gate pin 26 is over the channel layer 20.

In some embodiments, the substrate 10 includes silicon (Si), silicon carbide (SiC), gallium nitride (GaN), gallium oxide (Ga₂O₃), or sapphire. For example, the substrate 10 can be a bulk semiconductor substrate or include a composite substrate formed from different materials, and the substrate 10 can be doped (e.g., with P-typed or N-typed dopants) or undoped. The substrate 10 can also include a semiconductor-on-insulator (SOI) substrate, which is formed by forming semiconductor material on an insulating layer.

As shown in FIG. 1A, in some embodiments, the epitaxial layer 14 is formed over the substrate 10. For example, the material of the epitaxial layer 14 includes III-V group compound semiconductor materials, such as group III nitrides. In this embodiment, the epitaxial layer 14 includes gallium nitride (GaN) or gallium oxide (Ga₂O₃). The epitaxial layer 14 can be formed by an epitaxial growth process, such as molecular beam epitaxy (MBE), liquid phase epitaxy (LPE), metal-organic chemical vapor deposition (MOCVD), similar processes, or a combination thereof, but the embodiments of the invention are not limited thereto.

As shown in FIG. 1A, FIG. 1B, and FIG. 1C, in some embodiments, the epitaxial layer 14 has a top surface 14T. Through a surface treatment process, the top surface 14T is transformed into a rough interface 16T or a capture interface 16T′. The surface treatment process can be an ion bombardment process or an ion implantation process. The rough interface 16T is used to disrupt the atomic structure of the top surface 14T, thereby disrupting the two-dimensional electron gas; the ions doped in the capture interface 16T′ can be used to capture the two-dimensional electron gas.

As shown in FIG. 1B, through an ion bombardment process, the top surface 14T of the epitaxial layer 14 can be bombarded with ions (also known as physical bombardment) to transform the top surface 14T into a rough interface 16T, thereby suppressing the two-dimensional electron gas (2DEG) generated due to the polarization in the epitaxial layer 14 (i.e., disrupting the atomic structure of the top surface 14T). The rough interface 16T is a non-flat surface with an average roughness (Ra) that is greater than about 15 nm and less than about 50 nm. The ion bombardment process can use an inert gas or an etching gas, where the inert gas includes argon (Ar), and the etching gas includes chlorine (Cl₂).

As shown in FIG. 1C, through an ion implantation process, ion doping is performed on the top surface 14T of the epitaxial layer 14 to form a trapping region (also known as capture interface 16T′) near the top surface 14T, thereby trapping the two-dimensional electron gas (2DEG) generated due to polarization in the epitaxial layer 14. The capture interface 16T′ is a flat surface. The ion implantation process dopes ions into the top surface 14T, where the ions include at least one of fluorine (F), oxygen (O), nitrogen (N), iron (Fe), boron (B), magnesium (Mg), or silicon (Si), or a combination thereof. Additionally, the doping concentration of the capture interface 16T′ must be at least sufficient to suppress the two-dimensional electron gas (2DEG). That is, the doping concentration of the capture interface 16T′ can be at least greater than about 1×10¹⁸ cm⁻³, for example, 2×10¹⁸ cm⁻³.

As shown in FIG. 1A, in some embodiments, the barrier layer 18 is formed on the interface 16. In other words, the barrier layer 18 is in contact with the rough interface 16T as shown in FIG. 1B or the capture interface 16T′ as shown in FIG. 1C. In this embodiment, the barrier layer 18 includes aluminum gallium nitride (AlₓGa₍₁₋ₓ₎N), indium gallium nitride (InₓGa₍₁₋ₓ₎N), or aluminum gallium oxide ((AlₓGa₍₁₋ₓ₎)₂O₃), where 0<x<1. For example, when the epitaxial layer 14 is gallium nitride, the barrier layer 18 can be aluminum gallium nitride or indium gallium nitride; when the epitaxial layer 14 is gallium oxide (Ga₂O₃), the barrier layer 18 can be aluminum gallium oxide, but the embodiments of the invention are not limited thereto. Similarly, the barrier layer 18 can be formed by a deposition process or an epitaxial growth process, as previously mentioned, which will not be repeated here.

As shown in FIG. 1A, in some embodiments, the channel layer 20 is formed on the barrier layer 18. The channel layer 20 can include the same or similar material as the epitaxial layer 14. The process for the channel layer 20 can follow deposition or epitaxial growth processes. In this embodiment, the channel layer 20 includes gallium nitride or gallium oxide. Moreover, the channel layer 20 forms a hole channel (also known as a P-typed channel layer) due to its polarization, which induces a two-dimensional hole gas (2DHG). Under these conditions, the P-typed channel layer can be applied to power semiconductor devices, such as P-typed enhanced-mode metal-oxide-semiconductor field-effect transistors (MOSFETs).

Generally, at the interface between the epitaxial layer 14 and the barrier layer 18, a two-dimensional electron gas (2DEG) is generated due to polarization, and at the interface between the barrier layer 18 and the channel layer 20, a two-dimensional hole gas (2DHG) is generated due to polarization, thereby inducing a polarization electric field between the barrier layer 18 and the channel layer 20, with the electric field direction from the channel layer 20 towards the epitaxial layer 14. The electron flow (also known as polarization electron flow) is in the opposite direction of the polarization electric field, moving from the two-dimensional electron gas (2DEG) at the interface of the epitaxial layer 14 and barrier layer 18 to the two-dimensional hole gas (2DHG) at the interface of the barrier layer 18 and channel layer 20.

However, as the polarization electron flow increases, the threshold voltage of the power semiconductor device increases, requiring a larger drain current to suppress the two-dimensional hole gas (2DHG). Due to the power semiconductor device 100 of the embodiment having a rough interface 16T as shown in FIG. 1B or a capture interface 16T′ as shown in FIG. 1C, it can effectively suppress (e.g., through the rough interface 16T) or capture (e.g., through the capture interface 16T′) the two-dimensional electron gas (2DEG), thereby reducing the polarization electron flow (which moves in the opposite direction of the polarization electric field, from the epitaxial layer 14 through the barrier layer 18 to the channel layer 20).

For example, in the embodiment shown in FIG. 1B, the rough interface 16T can disrupt the polarization direction produced by the epitaxial structure, thereby suppressing the formation of the two-dimensional electron gas (2DEG) (and the two-dimensional hole gas (2DHG)). In the embodiment where inert gas (e.g., argon, etc.) is used to bombard the top surface 14T of the epitaxial layer 14 to form the rough interface 16T, power used in the ion bombardment process is greater than about 20 W and less than about 55 W. If the power exceeds 55 W, it can destroy the structure of the epitaxial layer 14 itself, causing damage to the power semiconductor device 100. In the embodiment where etching gas (e.g., chlorine, etc.) is used to bombard the top surface 14T of the epitaxial layer 14 to form the rough surface 16T, the concentration of the etching gas is greater than about 20% and less than about 60%. If the concentration exceeds 60%, it can destroy the structure of the epitaxial layer 14 itself, causing damage to the power semiconductor device 100.

In the embodiment shown in FIG. 1C, the ions doped in the capture interface 16T′ can suppress the formation of the two-dimensional electron gas (2DEG) (and the two-dimensional hole gas (2DHG)). In this embodiment, power used in the ion implantation process is greater than about 150 W and less than about 300 W, or the duration time of the ion implantation process is greater than about 80 seconds and less than about 240 seconds. If the power is less than 150 W, or the duration is less than 80 seconds, the doping concentration of the ions can be not be sufficient to effectively suppress the two-dimensional electron gas (2DEG) (and the two-dimensional hole gas (2DHG)).

As shown in FIG. 1A, in some embodiments, a source pin 22 and a drain pin 24 are formed on two sides of the channel layer 20, respectively. More specifically, the source pin 22 and the drain pin 24 can be in direct contact with the channel layer 20 and can be partially embedded in the channel layer 20, but the embodiments of the invention are not limited thereto. In some embodiments, the source pin 22 and the drain pin 24 include gold (Au), aluminum (Al), titanium (Ti), tin (Sn), germanium (Ge), indium (In), nickel (Ni), cobalt (Co), platinum (Pt), tungsten (W), molybdenum (Mo), chromium (Cr), copper (Cu), lead (Pb), titanium/aluminum (Ti/Al) alloy, titanium/gold (Ti/Au) alloy, titanium/platinum (Ti/Pt) alloy, aluminum/gold (Al/Au) alloy, nickel/gold (Ni/Au) alloy or gold/nickel (Au/Ni) alloy, similar materials, or a combination thereof. For example, the source pin 22 and the drain pin 24 can be formed by a deposition process and a planarization process (e.g., chemical-mechanical polishing), but the embodiments of the invention are not limited thereto.

As shown in FIG. 1A, in some embodiments, a gate pin 26 is formed over the channel layer 20. More specifically, in the X-direction shown in FIG. 1A, the gate pin 26 is between the source pin 22 and the drain pin 24. In this embodiment, the gate pin 26 can include the same or similar material as the source pin 22 (or the drain pin 24) and can be formed by a deposition process, but the embodiments of the invention are not limited thereto.

Furthermore, as shown in FIG. 1A, in some embodiments, the power semiconductor device 100 further includes a gate dielectric layer 28 disposed between the channel layer 20 and the gate pin 26. In some embodiments, the gate dielectric layer 28 includes silicon dioxide (SiO₂), silicon nitride (SiN), silicon oxynitride (SiON), aluminum oxide (Al₂O₃), hafnium oxide (HfO₂), zirconium oxide (ZrO₂), or any other suitable material. The gate dielectric layer 28 can be formed by a deposition process, which will not be elaborated here, but the embodiments of the invention are not limited thereto.

Moreover, as shown in FIG. 1A, in some embodiments, the power semiconductor device 100 further includes a buffer layer 12 disposed between the substrate 10 and the epitaxial layer 14. In some embodiments, the buffer layer 12 is a single layer, which includes aluminum nitride (AlN). Alternatively, the buffer layer 12 is multi-layered, which includes an aluminum gallium nitride (AlGaN)/gallium nitride (GaN) superlattices/gallium oxide (Ga₂O₃) stack. The buffer layer 12 can further alleviate the lattice mismatches between the substrate 10 and the epitaxial layer 14, enhancing the crystal quality.

As shown in FIG. 1A, in some embodiments, the power semiconductor device 100 further includes spacers 30 disposed on both sides of (or around) the channel layer 20, the barrier layer 18, and the epitaxial layer 14. For example, the spacers 30 includes silicon dioxide, silicon nitride, silicon oxynitride, aluminum oxide, aluminum nitride, any other low-K dielectric material, or a combination thereof. Moreover, the spacers 30 can be formed by a deposition process, such as chemical vapor deposition, atomic layer deposition, spin coating, similar deposition processes, or a combination thereof, but the embodiments of the invention are not limited thereto.

In some embodiments, the thickness T12 of the buffer layer 12 is about 4 μm, the thickness T14 of the epitaxial layer 14 (including the thickness of interface 16, for example) is about 400 nm, the thickness T18 of the barrier layer 18 is about 1.5 nm, and the thickness T20 of the channel layer 20 is about 3 nm.

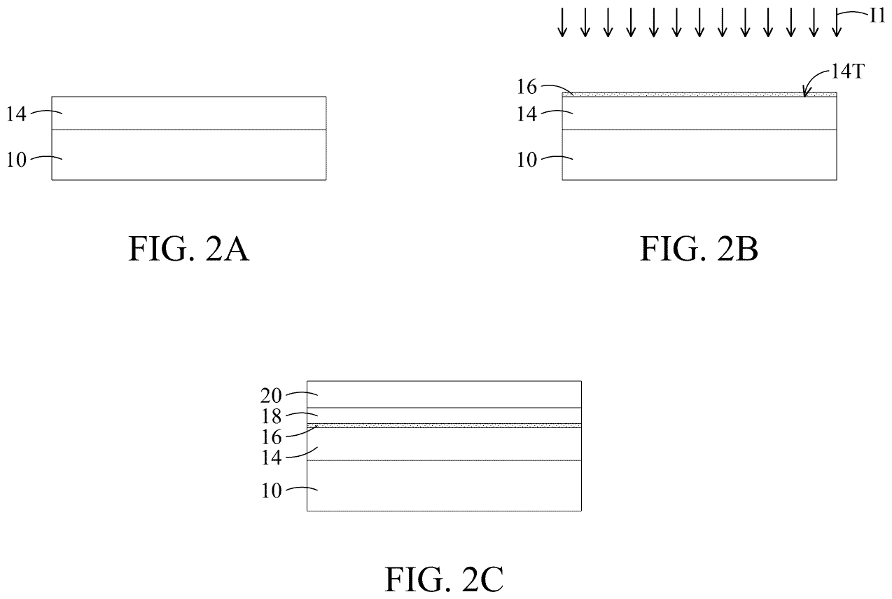

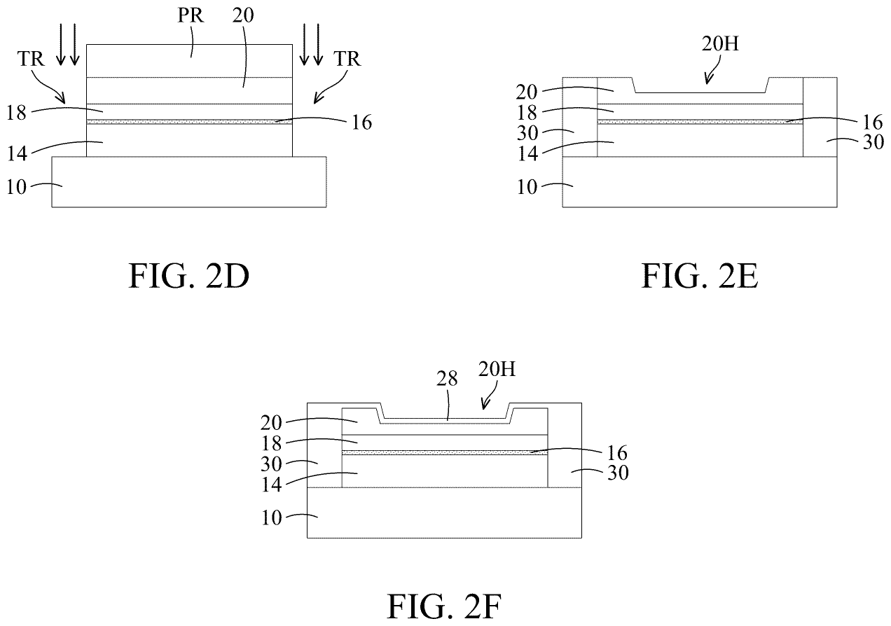

FIG. 2A to FIG. 2F are partial cross-sectional views illustrating various stages in manufacturing the power semiconductor device 100 according to some embodiments of the present invention. As shown in FIG. 2A to FIG. 2F, each stage in manufacturing the power semiconductor device 100 does not correspond exactly to the power semiconductor device 100 shown in FIG. 1A. For example, the buffer layer 12 is omitted in FIG. 2A to FIG. 2F. Similarly, some other components of the power semiconductor device 100 are also omitted in FIG. 2A to FIG. 2F for the sake of brevity.

As shown in FIG. 2A, an epitaxial layer 14 is formed over the substrate 10, and the epitaxial layer 14 has a top surface 14T. As shown in FIG. 2B, a surface treatment process I1 is performed to form an interface 16 on the top surface 14T of the epitaxial layer 14 (e.g., the rough interface 16T as shown in FIG. 1B or the capture interface 16T′ as shown in FIG. 1C), which can suppress or capture the potential two-dimensional electron gas (2DEG) that can form between the epitaxial layer 14 and the subsequently formed barrier layer 18. In one embodiment, the surface treatment process I1 includes bombarding the top surface 14T of the epitaxial layer 14 with an inert gas or an etching gas (i.e., forming the rough interface 16T as shown in FIG. 1B), thereby disrupting the atomic structure of the top surface 14T and suppressing the formation of the two-dimensional electron gas (2DEG). Alternatively, in another embodiment, the surface treatment process I1 includes doping ions on the top surface 14T of the epitaxial layer 14 (i.e., forming the capture interface 16T′ as shown in FIG. 1C) to capture the two-dimensional electron gas (2DEG) by the doped ions.

As shown in FIG. 2C, a barrier layer 18 is formed on the interface 16, and a channel layer 20 is formed on the barrier layer 18. Then, in some embodiments, a patterning process is performed on both sides of (or around) the channel layer 20, the barrier layer 18, and the epitaxial layer 14 to remove portions of the channel layer 20, the barrier layer 18, and the epitaxial layer 14. Specifically, as shown in FIG. 2D, a mask layer PR is disposed over the channel layer 20, and then the mask layer PR is used as an etching mask to perform an etching process to etch the channel layer 20, the barrier layer 18, and the epitaxial layer 14 to form the trench TR.

For example, the mask layer PR includes photoresist, such as positive photoresist or negative photoresist. Additionally, the mask layer includes a hard mask, which can be formed from silicon dioxide (SiO₂), silicon nitride (SiN), silicon oxynitride (SiON), silicon carbide (SiC), silicon carbonitride (SiCN), similar materials, or a combination thereof. The mask layer PR can be a single-layer structure or a multi-layer structure. The mask layer PR can be formed by a deposition process, a photolithography process, any other suitable process, or a combination thereof.

For example, the deposition process includes spin-on coating, chemical vapor deposition, atomic layer deposition, similar processes, or a combination thereof. The photolithography process includes coating of photoresist (e.g., spin coating), soft baking, mask aligning, exposure, post-exposure baking (PEB), developing, rinsing, drying (e.g., hard baking), any other suitable process, or a combination thereof.

As shown in FIG. 2E, a spacer is formed in the trench TR. Then, a recess 20H are formed in the channel layer 20. For example, the recess 20H can be formed by a patterning process. The dimension of the recess 20H can be adjusted according to actual needs.

As shown in FIG. 2F, a gate dielectric layer 28 is formed on the channel layer 20. Specifically, the gate dielectric layer 28 can be filled into (the bottom and sidewalls of) the recess 20H. Then, a source pin 22 and a drain pin 24 are formed on both sides of the channel layer 20, and a gate pin 26 is formed on the channel layer 20, thereby forming the power semiconductor device 100 as shown in FIG. 1A. As shown in FIG. 1A, part of the gate pin 26 can also be filled into the recess 20H shown in FIG. 2F.

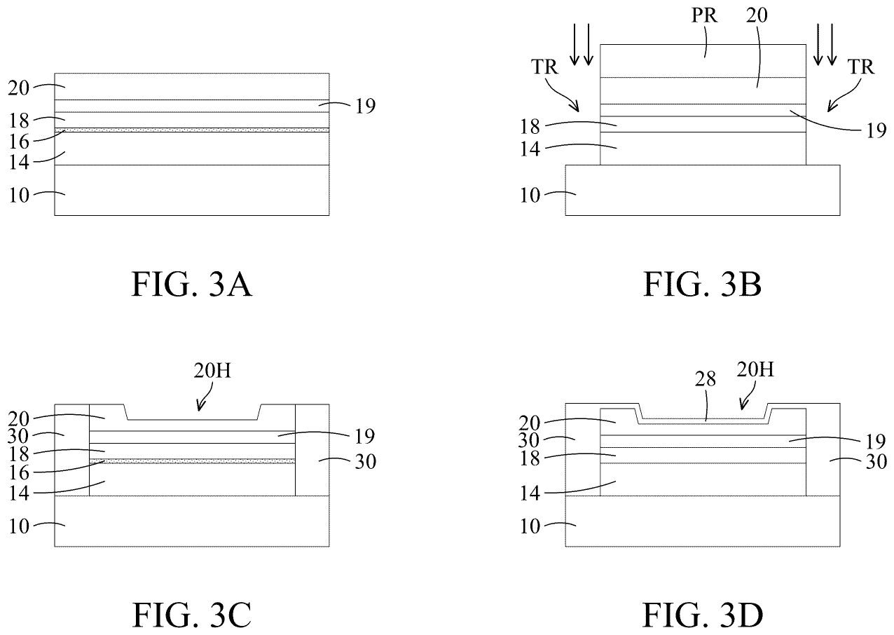

FIG. 3A to FIG. 3D are partial cross-sectional views illustrating various stages in manufacturing another power semiconductor device according to some other embodiments of the present invention. For example, the step shown in FIG. 3A can follow the step shown in FIG. 2B.

As shown in FIG. 3A, a barrier layer 18, an unintentionally doped (UID) layer 19, and a channel layer 20 are sequentially formed on the interface 16. In other words, in this embodiment, the power semiconductor device further includes an unintentionally doped layer 19 disposed between the barrier layer 18 and the channel layer 20. The unintentionally doped layer 19 can further suppress the formation of two-dimensional hole gas (2DHG).

Then, in some embodiments, a patterning process is performed on both sides of (or around) the channel layer 20, the unintentionally doped layer 19, the barrier layer 18, and the epitaxial layer 14 to remove portions of the channel layer 20, the unintentionally doped layer 19, the barrier layer 18, and the epitaxial layer 14. Specifically, as shown in FIG. 3B, a mask layer PR is disposed on the channel layer 20, and then the mask layer PR is used as an etching mask to perform an etching process to etch the channel layer 20, the unintentionally doped layer 19, the barrier layer 18, and the epitaxial layer 14 to form the trench TR.

As shown in FIG. 3C, a spacer 30 is formed in the trenches TR. Then, a recess 20H is formed in the channel layer 20. As shown in FIG. 3D, a gate dielectric layer 28 is formed on the channel layer 20. Specifically, the gate dielectric layer 28 can be filled into (the bottom and sidewalls of) the recess 20H. Then, a source pin 22 and a drain pin 24 are formed on both sides of the channel layer 20, and a gate pin 26 is formed on the channel layer 20, thereby forming another power semiconductor device that includes the unintentionally doped layer 19.

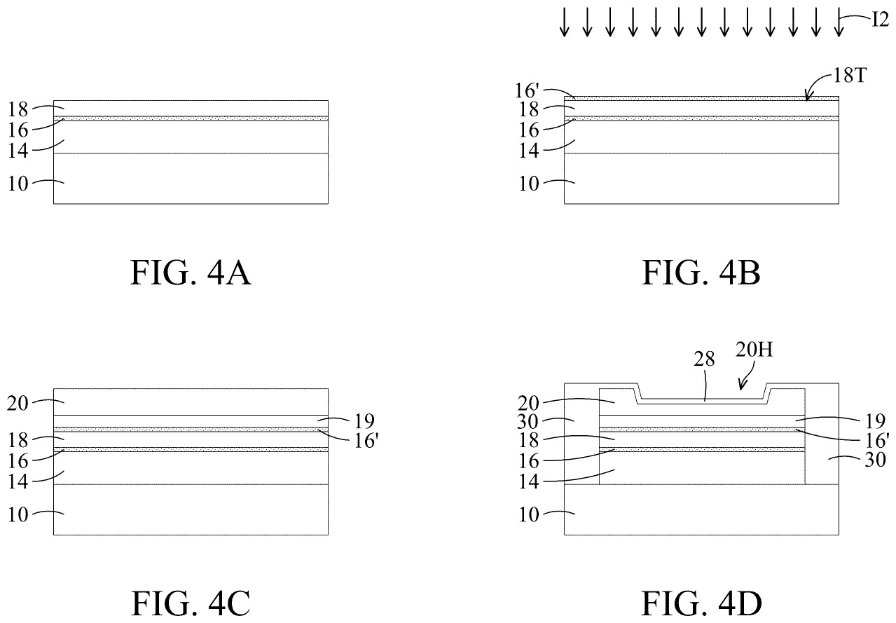

FIG. 4A to FIG. 4D are partial cross-sectional views illustrating various stages in manufacturing another power semiconductor device according to some other embodiments of the present invention. For example, the step shown in FIG. 4A follows the step shown in FIG. 2B.

As shown in FIG. 4A, a barrier layer 18 is formed on the interface 16 (e.g., the rough interface 16T as shown in FIG. 1B or the capture interface 16T′ as shown in FIG. 1C). Then, as shown in FIG. 4B, another surface treatment process 12 is performed to form an interface 16′ on the top surface 18T of the barrier layer 18, which can suppress or capture the potential two-dimensional hole gas (2DHG) that can form between the barrier layer 18 and the subsequently formed channel layer 20. In other words, in this embodiment, the top surface 18T of the barrier layer 18 (i.e., the interface 16′) is a rough interface (e.g., similar to the rough interface 16T as shown in FIG. 1B) or a capture interface doped with ions (e.g., similar to the capture interface 16T′ as shown in FIG. 1C). In one embodiment, the surface treatment process 12 includes bombarding the top surface 18T of the barrier layer 18 with an inert gas or an etching gas (i.e., forming a rough interface similar to 16T as shown in FIG. 1B), thereby disrupting the atomic structure of the top surface 18T and suppressing the formation of two-dimensional hole gas (2DHG). Alternatively, in another embodiment, the surface treatment process 12 includes doping ions on the top surface 18T of the barrier layer 18 (i.e., forming a capture interface similar to 16T′ as shown in FIG. 1C) to capture the two-dimensional hole gas (2DHG) by the doped ions.

As shown in FIG. 4C, an unintentionally doped (UID) semiconductor layer 19 and a channel layer 20 are sequentially formed on the interface 16′. Then, in some embodiments, a patterning process is performed on both sides of (or around) the channel layer 20, the unintentionally doped layer 19, the barrier layer 18, and the epitaxial layer 14 to remove portions of the channel layer 20, the unintentionally doped layer 19, the barrier layer 18, and the epitaxial layer 14.

As shown in FIG. 4D, a gate dielectric layer 28 is formed on the channel layer 20. Specifically, the gate dielectric layer 28 can be filled into (the bottom and sidewalls of) the recess 20H. Then, a source pin 22 and a drain pin 24 are formed on both sides of the channel layer 20, and a gate pin 26 is formed on the channel layer 20, thereby forming another power semiconductor device that includes the unintentionally doped layer 19 (and interface 16′).

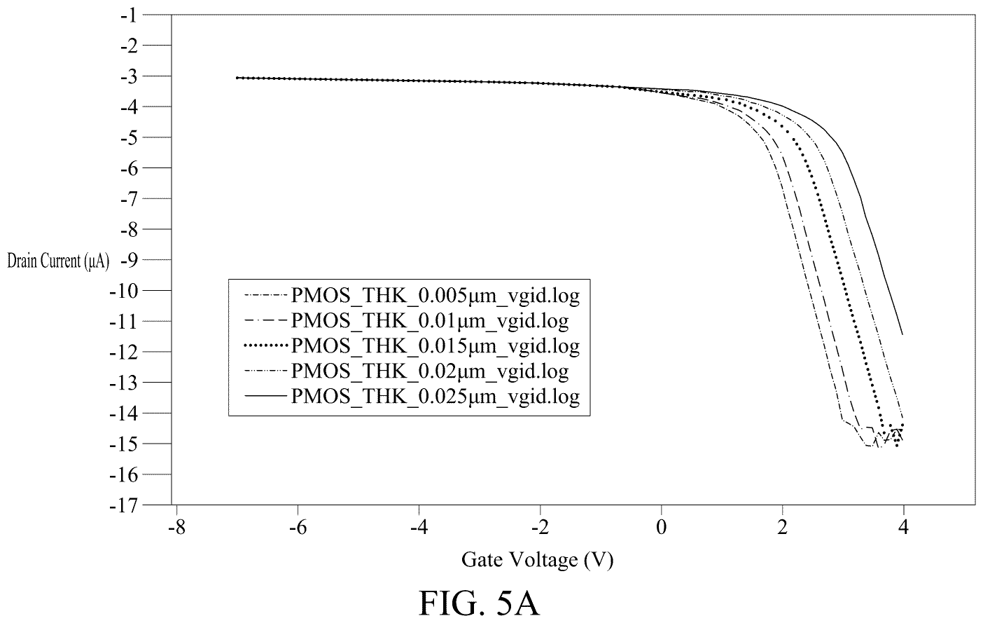

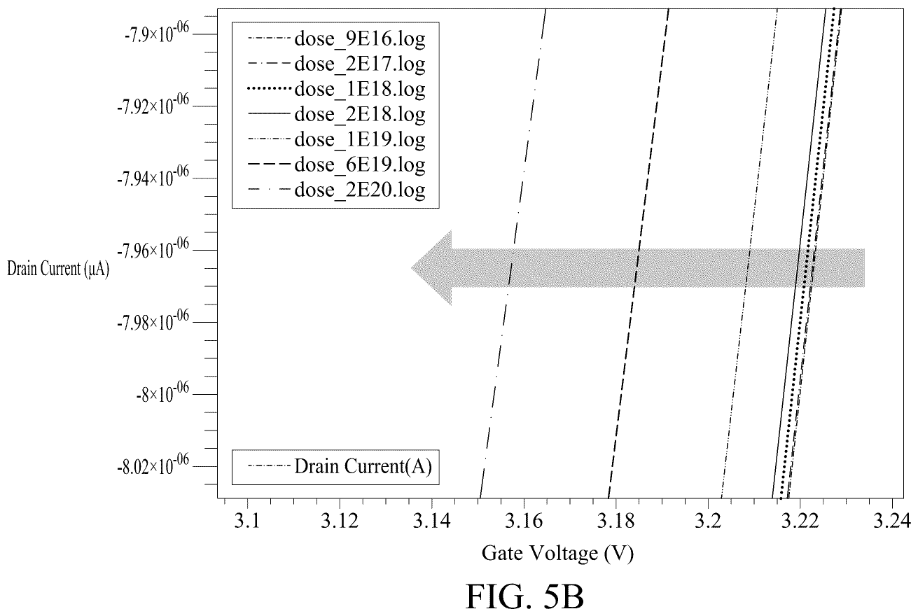

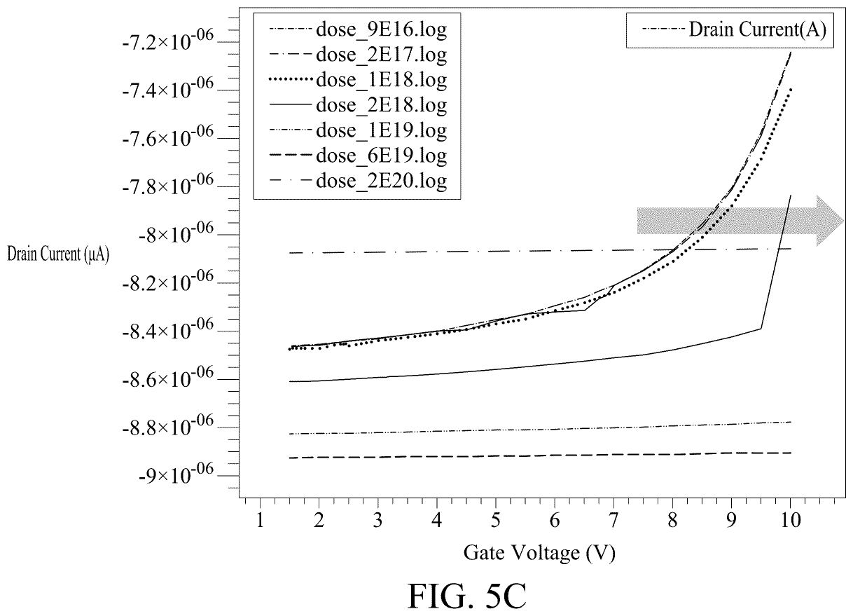

FIG. 5A illustrates the drain current (μA)—gate voltage (V) electrical characteristic curves of the power semiconductor device 100 for different thicknesses T20 of the channel layer 20 (see FIG. 1A). In FIG. 5A, PMOS_THK_0.005 μm_vgid.log indicates the thickness T20 of the channel layer 20 is about 5 nm, PMOS_THK_0.01 μm_vgid.log indicates the thickness T20 of the channel layer 20 is about 10 nm, PMOS_THK_0.015 μm_vgid.log indicates the thickness T20 of the channel layer 20 is about 15 nm, PMOS_THK_0.02 μm_vgid.log indicates the thickness T20 of the channel layer 20 is about 20 nm, and PMOS_THK_0.025 μm_vgid.log indicates the thickness T20 of the channel layer 20 is about 25 nm. As shown in FIG. 5A, as the thickness T20 of the channel layer 20 increases, the threshold voltage of the power semiconductor device 100 moves positively, requiring a higher gate voltage to deplete the two-dimensional hole gas (2DHG). Therefore, in some embodiments, when the thickness T20 of the channel layer 20 is less than about 20 nm, the drain current can increase from −15 microamperes (μA) to −11.5 microamperes (μA) at a gate voltage of 4 volts. That is, as the thickness T20 of the channel layer 20 increases, the drain current (μA) of the PMOS power semiconductor device also increases.

FIG. 5B illustrates the drain current (μA)—gate voltage (V) electrical characteristic curves of the power semiconductor device 100 when the interface 16 (i.e., the capture interface 16T′) is doped with silicon (Si) at different concentrations. In FIG. 5B, dose_9E16.log indicates a silicon implantation concentration of about 9×10¹⁶ cm⁻³, dose_2E17.log indicates a silicon implantation concentration of about 2×10¹⁷ cm⁻³, dose_1E18.log indicates a silicon implantation concentration of about 1×10¹⁸ cm⁻³, dose_2E18.log indicates a silicon implantation concentration of about 2×10¹⁸ cm⁻³, dose_1E19.log indicates a silicon implantation concentration of about 1×10¹⁹ cm⁻³, dose_6E19.log indicates a silicon implantation concentration of about 6×10¹⁹ cm⁻³, and dose_2E20.log indicates a silicon implantation concentration of about 2×10²⁰ cm⁻³. As shown in FIG. 5B, as the silicon implantation concentration in the interface 16 increases, the threshold voltage of the power semiconductor device 100 moves negatively (i.e., in the direction of the arrow in FIG. 5B), altering the transistor characteristics of the power semiconductor device 100 from depletion mode to enhanced mode. In other words, the higher the silicon implantation concentration in interface 16, the more effective it is in suppressing the two-dimensional electron gas (2DEG) and two-dimensional hole gas (2DHG) generated due to polarization in the epitaxial layer 14. In some embodiments, when the silicon implantation concentration in interface 16 is greater than about 2×10¹⁸ cm⁻³, it increases the PMOS threshold voltage, thereby forming enhanced-mode transistor characteristics.

FIG. 5C illustrates the drain current (μA)-gate voltage (V) electrical characteristic curves of the power semiconductor device 100 when the interface 16 (i.e., the capture interface 16T′) is doped with magnesium (Mg) at different concentrations. In FIG. 5C, dose_9E16.log indicates a magnesium implantation concentration of about 9×10¹⁶ cm⁻³, dose_2E17.log indicates a magnesium implantation concentration of about 2×10¹⁷ cm⁻³, dose_1E18.log indicates a magnesium implantation concentration of about 1×10¹⁸ cm⁻³, dose_2E18.log indicates a magnesium implantation concentration of about 2×10¹⁸ cm⁻³, dose_1E19.log indicates a magnesium implantation concentration of about 1×10¹⁹ cm⁻³, dose_6E19.log indicates a magnesium implantation concentration of about 6×10¹⁹ cm⁻³, and dose_2E20.log indicates a magnesium implantation concentration of about 2×10²⁰ cm⁻³. As shown in FIG. 5C, as the magnesium implantation concentration in the interface 16 increases, the threshold voltage of the power semiconductor device 100 shifts towards negative bias (in the direction of the arrow in FIG. 5C), hence transitioning P-typed transistor operation from depletion mode to enhanced mode.

According to some embodiments of the present invention above, the power semiconductor device includes an epitaxial layer with a rough interface or a capture interface, which can suppress or capture two-dimensional electron gas (2DEG) generated due to polarization at the top surface of the epitaxial layer. When the power semiconductor device of the present invention is a PMOS device, it can enhance the current characteristics of the PMOS device by suppressing or capturing two-dimensional electron gas (2DEG). Alternatively, it can also suppress the two-dimensional hole gas (2DHG) generated due to polarization in the epitaxial layer, thereby forming an enhanced-mode PMOS device.

What is claimed is:

1. A power semiconductor device, comprising:
a substrate;
an epitaxial layer over the substrate and having a top surface, wherein the top surface is a rough interface or a capture interface doped with ions, the rough interface is used to disrupt an atomic structure of the top surface, thereby breaking down a two-dimensional electron gas, and the ions doped in the capture interface are used to trap the two-dimensional electron gas;
a barrier layer in contact with the top surface of the epitaxial layer;
a channel layer disposed on the barrier layer;
a source pin and a drain pin respectively disposed on two sides of the channel layer; and
a gate pin disposed over the channel layer.

2. The power semiconductor device as claimed in claim 1, wherein an average roughness of the rough interface is greater than 15 nm and less than 50 nm.

3. The power semiconductor device as claimed in claim 1, wherein the ions comprise at least one of fluorine, oxygen, nitrogen, iron, boron, magnesium, and silicon.

4. The power semiconductor device as claimed in claim 1, wherein a doping concentration of the capture interface is greater than 1×10¹⁸ cm⁻³.

5. The power semiconductor device as claimed in claim 1, further comprising:
an unintentionally doped layer disposed between the barrier layer and the channel layer.

6. The power semiconductor device as claimed in claim 5, wherein a top surface of the barrier layer is a rough interface or a capture interface doped with ions, the rough interface is used to disrupt an atomic structure of the top surface of the barrier layer, thereby breaking down the two-dimensional electron gas, and the ions doped in the capture interface are used to trap the two-dimensional electron gas.

7. The power semiconductor device as claimed in claim 1, wherein the epitaxial layer and the channel layer comprise gallium nitride or gallium oxide.

8. The power semiconductor device as claimed in claim 7, wherein the barrier layer comprises aluminum gallium nitride, indium gallium nitride, or aluminum gallium oxide.

9. The power semiconductor device as claimed in claim 1, wherein the channel layer is a P-typed channel layer.

10. The power semiconductor device as claimed in claim 1, further comprising:
a buffer layer disposed between the substrate and the epitaxial layer.

11. A method of manufacturing a power semiconductor device, suitable for suppressing or capturing two-dimensional electron gas, the power semiconductor device comprising a substrate and an epitaxial layer over the substrate, the epitaxial layer having a top surface, the method comprising:
deforming the top surface into a rough interface or doping the top surface to form a capture interface by a surface treatment process;
forming a barrier layer on the epitaxial layer;
forming a channel layer on the barrier layer;
forming a source pin and a drain pin on two sides of the channel layer respectively; and
forming a gate pin over the channel layer.

12. The method of manufacturing the power semiconductor device as claimed in claim 11, wherein the surface treatment process is an ion bombardment process, and the ion bombardment process comprises bombarding the top surface of the epitaxial layer with an inert gas or an etching gas to deform the top surface into the rough interface, thereby disrupting an atomic structure of the top surface.

13. The method of manufacturing the power semiconductor device as claimed in claim 12, wherein the inert gas comprises argon, and the etching gas comprises chlorine.

14. The method of manufacturing the power semiconductor device as claimed in claim 12, wherein a concentration of the etching gas is greater than 20% and less than 60%, or power used in the ion bombardment process is greater than 20 W and less than 55 W.

15. The method of manufacturing the power semiconductor device as claimed in claim 11, wherein the surface treatment process is an ion implantation process, the implantation process comprises doping ions on the top surface to capture the two-dimensional electron gas generated due to polarization of the top surface, and the ions comprises at least one of fluorine, oxygen, nitrogen, iron, boron, magnesium, and silicon.

16. The method of manufacturing the power semiconductor device as claimed in claim 15, wherein power used in the ion implantation process is greater than 150 W and less than 300 W, or a duration time of the ion implantation process is greater than 80 seconds and less than 240 seconds.
